(19) United States
(12) Patent Application Publication
(10) Pub. No.: US 2024/0015884 A1
(43) Pub. Date: Jan. 11, 2024

(54) WIRING CIRCUIT BOARD AND METHOD FOR PRODUCING WIRING CIRCUIT BOARD

(71) Applicant: NITTO DENKO CORPORATION, Osaka (JP)

(72) Inventors: Shusaku SHIBATA, Osaka (JP); Takahiro IKEDA, Osaka (JP); Teppei NIINO, Osaka (JP)

(73) Assignee: NITTO DENKO CORPORATION, Osaka (JP)

(21) Appl. No.: 18/252,308

(22) PCT Filed: Oct. 28, 2021
(86) PCT No.: PCT/JP2021/039762

§ 371 Date: May 9, 2023

(30) Foreign Application Priority Data
Nov. 13, 2020 (JP) 2020-189117

(51) Int. Cl. H05K 1/02; H05K 3/42; H05K 3/40; H05K 1/09

(52) U.S. Cl. CPC H05K 1/0298; H05K 3/429; H05K 3/4076; H05K 1/092; H05K 2201/0338

(57) ABSTRACT

Provided is a wiring circuit board that includes a metal supporting board; a first metal thin film; an insulating layer; a second metal thin film; and a conductive layer in order toward one side in a thickness direction. The metal supporting board includes a metal supporting layer and a surface metal layer. The surface metal layer is disposed on one surface in the thickness direction of the metal supporting layer and has higher conductivity than the metal supporting layer. The insulating layer has a through hole. The conductive layer has a via portion. The via portion is disposed in the through hole and is electrically connected to the metal supporting board.

### TECHNICAL FIELD

The present invention relates to a wiring circuit board and a method for producing the wiring circuit board.

### BACKGROUND ART

There has been known a wiring circuit board including a supporting substrate made of metal, an insulating layer on the supporting substrate, and a wiring pattern on the insulating layer. In this wiring circuit board, the supporting substrate has a multilayer structure, for example, in order to secure good performance in the wiring pattern. The technique for the wiring circuit board is disclosed in, for example, Patent Document 1 below. The supporting substrate of the wiring circuit board described in Patent Document 1 has a multilayer structure including a metal supporting board, and a metal foil disposed on the wiring pattern side of this board.

### CITATION LIST

### Patent Document

Patent Document 1: Japanese Unexamined Patent Publication No. 2007-157836

### SUMMARY OF THE INVENTION

### Problem to be Solved by the Invention

The supporting substrate of the wiring circuit board of Patent Document 1 has a metal thin film for forming the metal foil between the metal supporting board and the metal foil. The metal thin film is a plating seed layer for forming the metal foil. In one wiring circuit board, which is specifically described in Patent Document 1, the metal supporting board is made of stainless steel, the metal foil is made of copper, and the metal thin film is made of chromium.

In the process of producing the wiring circuit board, however, the supporting substrate cannot be effectively patterned in a single wet etching process (the supporting substrate is patterned, for example, during trimming of the supporting substrate). This is because an etchant to the metal supporting board of stainless steel and the metal foil of copper that are included in the supporting substrate is different from an etchant to the metal thin film of chromium.

In the meantime, a via hole that penetrates the insulating layer in the thickness direction to connect to the supporting substrate and the wiring pattern may be provided in the wiring circuit board. The supporting substrate and the wiring pattern are electrically connected through the via. In such a wiring circuit board, there is a need to reduce the resistance of the electrical connection between the supporting substrate and the wiring pattern.

The present invention provides a wiring circuit board and a method for producing the wiring circuit board which are suitable for establishing a low-resistance electrical connection between the metal supporting board and a wiring layer formed on the insulating layer of this board, and are suitable for efficiently patterning the metal supporting board.

### Means for Solving the Problem

The present invention [1] includes a wiring circuit board including a metal supporting board; a first metal thin film; an insulating layer; a second metal thin film; and a conductive layer in order toward one side in a thickness direction, the metal supporting board including a metal supporting layer, and a surface metal layer disposed on one surface in the thickness direction of the metal supporting layer and having higher conductivity than the metal supporting layer, the insulating layer having a through hole that penetrates the insulating layer in the thickness direction, the conductive layer having a via portion that is disposed in the through hole and is electrically connected to the metal supporting board.

The present invention [2] includes the wiring circuit board described in [1], in which the metal supporting layer includes at least one kind selected from the group consisting of stainless steel, copper alloy, aluminum, nickel, and titanium.

The present invention [3] includes the wiring circuit board described in [1] or [2], in which the surface metal layer includes at least one kind selected from the group consisting of gold, silver, and copper.

The present invention [4] includes the wiring circuit board described in any one of the above-described [1] to [3], in which the via portion is electrically connected to the metal supporting board through the first metal thin film and the second metal thin film.

The present invention [5] includes the wiring circuit board described in any one of the above-described [1] to [3], in which the first metal thin film has an opening that is opened along the through hole, and the via portion is electrically connected to the metal supporting board through the second metal thin film.

The present invention [6] includes a method for producing a wiring circuit board, including a first metal thin film forming step of forming a first metal thin film on one surface in the thickness direction of a metal supporting board including a metal supporting layer, and a surface metal layer disposed on one surface in the thickness direction of the metal supporting layer and having higher conductivity than the metal supporting layer; an insulating layer forming step of forming an insulating layer on one surface in the thickness direction of the first metal thin film, the insulating layer having a through hole; a second metal thin film forming step of forming a second metal thin film on one surface in the thickness direction of the insulating layer and on a portion of the first metal thin film, the portion being exposed in the through hole; and a conductive layer forming step of forming a conductive layer on one surface in the thickness direction of the second metal thin film, the conductive layer including a via portion disposed in the through hole.

The present invention [7] includes a method for producing a wiring circuit board, including a first metal thin film forming step of forming a first metal thin film on one surface in the thickness direction of a metal supporting board including a metal supporting layer and a surface metal layer disposed on one surface in the thickness direction of the metal supporting layer and having higher conductivity than the metal supporting layer; an insulating layer forming step of forming an insulating layer on one surface in the thickness direction of the first metal thin film, the insulating layer having a through hole; a removing step of removing a portion of the first metal thin film, the portion being exposed in the through hole, to expose the metal supporting board in the through hole; a second metal thin film forming step of forming a second metal thin film on one surface in the thickness direction of the insulating layer and on a portion of the metal supporting board exposed in the through hole; and a conductive layer forming step of forming a conductive layer on one surface in the thickness direction of the second metal thin film, the conductive layer including a via portion disposed in the through hole.

### Effects of the Invention

In the wiring circuit board of the present invention, as described above, the metal supporting board includes a metal supporting layer, and a surface metal layer disposed on one surface in the thickness direction of the metal supporting layer and having higher conductivity than the metal supporting layer. This configuration is suitable for establishing a low-resistance electrical connection between the conductive layer disposed on one side in the thickness direction of the metal supporting board and the metal supporting board.

In the wiring circuit board of the present invention, as described above, the surface metal layer having higher conductivity than the metal supporting layer is disposed on one surface in the thickness direction of the metal supporting layer. Such a configuration, in which the metal supporting layer and the surface metal layer are directly in contact with each other without the other layer interposed therebetween, is suitable for efficiently patterning the metal supporting board by subjecting the metal supporting board to a single process (e.g., wet etching process).

The method for producing the wiring circuit board according to the present invention is suitable for producing the wiring circuit board of this type.

### BRIEF DESCRIPTION OF THE DRAWINGS

FIG. 1 is a fragmentary sectional view of an embodiment of a wiring circuit board of the present invention.

FIG. 2 is an enlarged sectional view of a portion of the wiring circuit board shown in FIG. 1.

FIGS. 3A to 3C represent a part of the steps in the method for producing the wiring circuit board shown in FIG. 1: FIG. 3A represents a preparation step, FIG. 3B represents a first metal thin film forming step, and FIG. 3C represents a base insulating layer forming step.

FIGS. 4A to 4D represent steps subsequent to the step shown in FIG. 3C: FIG. 4A represents a second metal thin film forming step, FIG. 4B represents a conductive layer forming step, FIG. 4C represents an etching step, and FIG. 4D represents a cover insulating layer forming step.

FIG. 5 is a fragmentary sectional view of another embodiment of the wiring circuit board of the present invention.

FIG. 6 is an enlarged sectional view of a portion of the wiring circuit board shown in FIG. 5.

FIGS. 7A to 7C represent a part of the steps in the method for producing the wiring circuit board shown in FIG. 5: FIG. 7A represents a removing step, FIG. 7B represents a second metal thin film forming step, and FIG. 7C represents a conductive layer forming step.

FIGS. 8A to 8B represent steps subsequent to the step shown in FIG. 7C: FIG. 8A represents an etching step, and FIG. 8B represents a cover insulating layer forming step.

### DESCRIPTION OF THE EMBODIMENTS

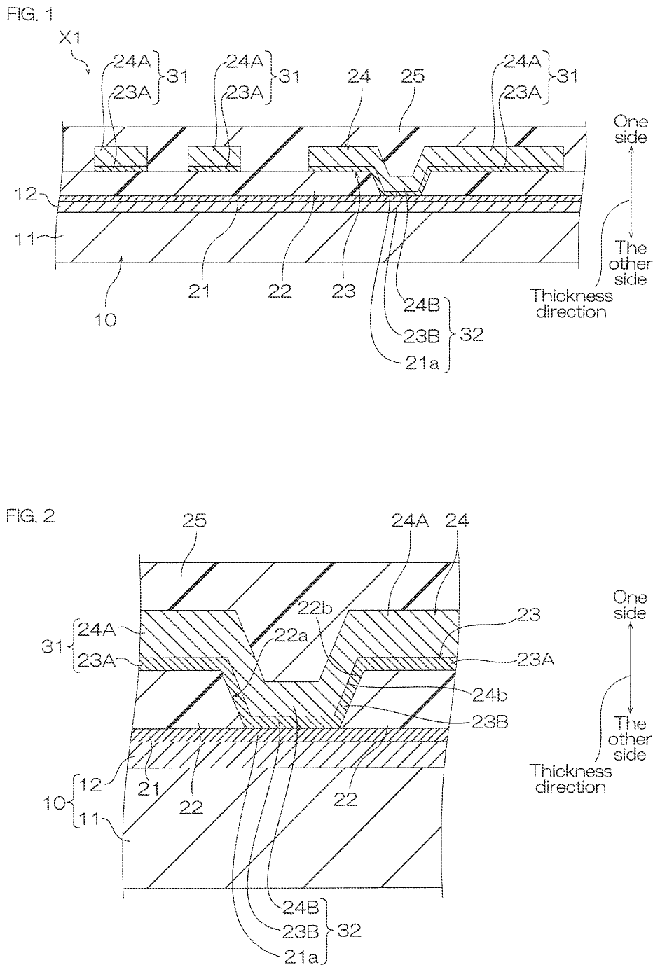

As shown in FIGS. 1 and 2, a wiring circuit board X1, which is an embodiment of the wiring circuit board of the present invention, includes a metal supporting board 10, a first metal thin film 21, an insulating layer 22 as a base insulating layer, a second metal thin film 23, a conductive layer 24, and an insulating layer 25 as a cover insulating layer in order toward one side in a thickness direction. The wiring circuit board X1 extends in a direction (plane direction) orthogonal to the thickness direction and has a predetermined shape in plan view.

The metal supporting board 10 includes a metal supporting layer 11 and a surface metal layer 12.

The metal supporting layer 11 is a substrate for securing strength of the wiring circuit board X1. Examples of a material of the metal supporting layer 11 include stainless steel, copper, copper alloy, aluminum, nickel, titanium, and 42 alloy. Examples of the stainless steel include SUS304 according to the AISI (American Iron and Steel Institute) standard. In terms of the strength of the metal supporting layer 11, the metal supporting layer 11 preferably contains at least one kind selected from the group consisting of stainless steel, copper alloy, aluminum, nickel, and titanium, and is more preferably formed of at least one kind selected from the group consisting of stainless steel, copper alloy, aluminum, nickel, and titanium. The metal supporting layer 11 is preferably formed of copper alloy in terms of achieving both the strength and conductivity of the metal supporting layer 11. The metal supporting layer 11 has a thickness of, for example, 15 μm or more. The metal supporting layer 11 has a thickness of, for example, 500 μm or less, preferably 250 μm or less.

The surface metal layer 12 is disposed on one surface in the thickness direction of the metal supporting layer 11 (the surface metal layer 12 is in contact with the metal supporting layer 11). In this embodiment, the surface metal layer 12 is disposed over the entire surface on one side in the thickness direction of the metal supporting layer 11. Examples of the surface metal layer 12 include a film formed by a sputtering method (sputtering film), a film formed by a plating method (plating film), and a film formed by a vacuum deposition method (vacuum deposition film).

The surface metal layer 12 has higher conductivity than the metal supporting layer 11. In terms of conductivity of the surface metal layer 12, the surface metal layer 12 preferably contains at least one kind selected from the group consisting of gold, silver, and copper, and is more preferably formed of at least one kind selected from the group consisting of gold, silver, and copper. The surface metal layer 12 is preferably formed of copper in terms of film formability of the surface metal layer 12 in a case where the metal supporting layer 11 is made of copper alloy.

The surface metal layer 12 has a thickness of preferably 0.5 μm or more, more preferably 3 μm or more.

The first metal thin film 21 is disposed on one surface in the thickness direction of the metal supporting board 10. In this embodiment, the first metal thin film 21 is disposed over the entire surface on one side in the thickness direction of the metal supporting board 10.

The first metal thin film 21 is a layer for securing adhesion of the insulating layer 22 to the metal supporting board 10. Examples of the first metal thin film 21 include a film formed by a sputtering method (sputtering film), a film formed by a plating method (plating film), and a film formed by a vacuum deposition method (vacuum deposition film).

Examples of a material of the first metal thin film 21 include chromium, nickel, and titanium. The material of the first metal thin film 21 may be an alloy containing two or more metals selected from the group consisting of chromium, nickel, and titanium. For the material of the first metal thin film 21, preferably, chromium is used.

The first metal thin film 21 has a thickness of, for example, 1 nm or more, preferably 10 nm or more, more preferably 20 nm or more. The first metal thin film 21 has a thickness of, for example, 10000 nm or less, preferably 1000 nm or less, more preferably 500 nm or less.

The insulating layer 22 is disposed on one surface in the thickness direction of the first metal thin film 21. Examples of a material of the insulating layer 22 include resin materials such as polyimide, polyether nitrile, polyethersulfone, polyethylene terephthalate, polyethylene naphthalate, and polyvinyl chloride (the same resin materials are also used as the material of the insulating layer 25 to be described later). The insulating layer 22 has a thickness of, for example, 1 μm or more, preferably 3 μm or more. The insulating layer 22 has a thickness of, for example, 35 μm or less.

The insulating layer 22 has a through hole 22a that penetrates the insulating layer 22 in the thickness direction. The through hole 22a has, for example, a generally circular shape in plan view. In this embodiment, the through hole 22a has an inner wall surface 22b that is inclined. The inner wall surface 22b is inclined so that a portion thereof closer to the metal supporting board 10 is disposed inwardly. That is, the inner wall surface 22b is inclined so that the opening cross-sectional area of the through hole 22a becomes smaller as the portion comes closer to the metal supporting board 10. The metal thin film 21 has a portion 21a facing the through hole 22a.

In this embodiment, the second metal thin film 23 is continuously disposed on one surface in the thickness direction of the insulating layer 22, on the inner wall surface 22b of the through hole 22a, and on the portion 21a of the first metal thin film 21 facing the through hole 22a. The second metal thin film 23 includes a second metal thin film 23A disposed outside the through hole 22a and a second metal thin film 23B disposed inside the through hole 22a. The second metal thin film 23B has a recessed shape, for example, in vertical section shown in FIG. 2. The second metal thin film 23A has a predetermined pattern shape on the insulating layer 22. The second metal thin film 23B is connected to the first metal thin film 21 in the through hole 22a. The second metal thin film 23A and the second metal thin film 23B are contiguous with each other.

The second metal thin film 23 is a seed layer for forming the conductive layer 24. Examples of the second metal thin film 23 include a sputtering film, a plating film, and a vacuum deposition film.

Examples of a material of the second metal thin film 23 include chromium, copper, nickel, and titanium. The material of the second metal thin film 23 may be an alloy containing two or more metals selected from the group consisting of chromium, copper, nickel, and titanium. For the material of the second metal thin film 23, preferably, chromium is used. The second metal thin film 23 may have a single layer structure or a multilayer structure of two or more layers. When the second metal thin film 23 has a multilayer structure, the second metal thin film 23 is formed of, for example, a chromium layer as an underlying layer and a copper layer on the chromium layer.

The second metal thin film 23 has a thickness of, for example, 1 nm or more, preferably 10 nm or more. The second metal thin film 23 has a thickness of, for example, 500 nm or less, preferably 200 nm or less.

The conductive layer 24 is disposed on one surface in the thickness direction of the second metal thin film 23. The conductive layer 24 includes a wire portion 24A disposed outside the through hole 22a and a via portion 24B disposed inside the through hole 22a. The wire portion 24A and the via portion 24B are contiguous with each other. The wire portion 24A has a predetermined pattern shape. The via portion 24B has a recessed shape, for example, in vertical section shown in FIG. 2. The via portion 24B has a circumferential side surface 24b that is inclined. The circumferential side surface 24b is inclined so that a portion thereof closer to the metal supporting board 10 is disposed inwardly. That is, the circumferential side surface 24b is inclined so that the cross-sectional area of the via portion 24B becomes smaller as the portion comes closer to the metal supporting board 10.

Examples of a material of the conductive layer 24 include copper, nickel, and gold. The material of the conductive layer 24 may be an alloy containing two or more metals selected from the group consisting of copper, nickel, and gold. For the material of the conductive layer 24, preferably, copper is used.

The second metal thin film 23A and the wire portion 24A on the second metal thin film 23A form a wiring layer 31 having a predetermined pattern shape on the insulating layer 22. In the through hole 22a, the portion 21a of the first metal thin film 21, the second metal thin film 23B, and the via portion 24B on the second metal thin film 23B form a via 32. The via 32 is connected to the surface metal layer 12 having higher conductivity than the metal supporting layer 11 in the metal supporting board 10. The metal supporting board 10 and the wiring layer 31 are electrically connected through the via 32. The wiring layer 31 may be grounded through the via 32 and the metal supporting board 10.

The wiring layer 31 has a thickness of, for example, 3 μm or more, preferably 5 μm or more. The wiring layer 31 has a thickness of, for example, 50 μm or less, preferably 30 μm or less. The wiring layer 31 has a width (a dimension in the direction orthogonal to the extending direction of the wiring layer 31) of, for example, 5 μm or more, preferably 8 μm or more. The wiring layer 31 has a width of, for example, 100 μm or less, preferably 50 μm or less.

The insulating layer 25 is disposed on one side in the thickness direction of the insulating layer 22 so as to cover the wiring layer 31 and the via 32. The insulating layer 25 may have an opening through which the wiring layer 31 and/or the via 32 are partially exposed. That is, the insulating layer 25 has an opening, and the wiring layer 31 and/or the via 32 may be exposed in the opening. In the wiring layer 31 and/or the via 32, the portion exposed in the opening can work as, for example, a terminal portion of the wiring circuit board X1. Such insulating layer 25 has a thickness of, for example. 4 μm or more, preferably 6 μm or more. The insulating layer 25 has a thickness of, for example, 60 μm or less, preferably 40 μm or less.

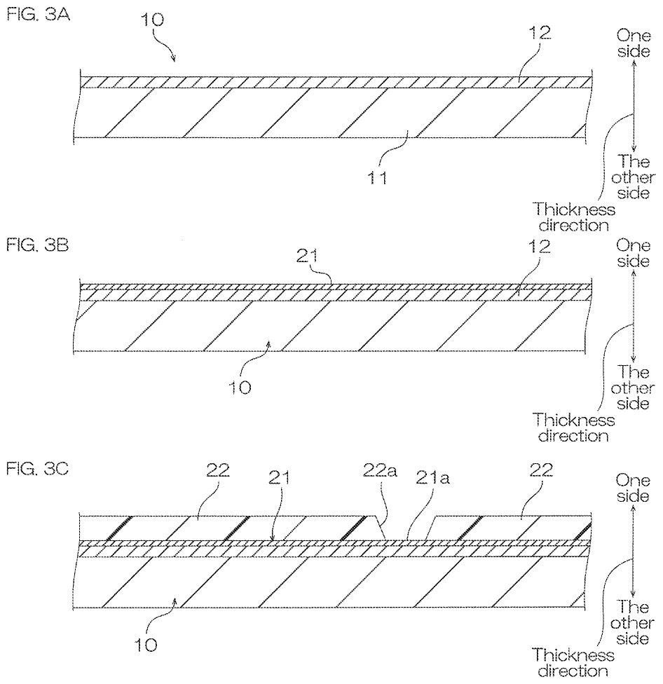

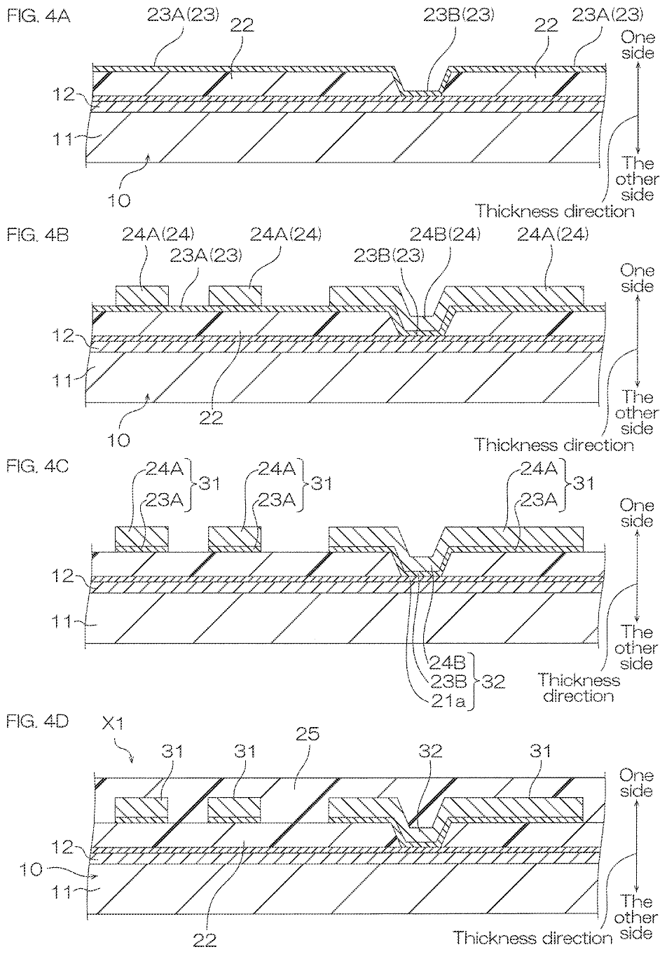

FIGS. 3A to 3C and 4A to 4D represent a method for producing the wiring circuit board X1 as an embodiment of the method for producing the wiring circuit board according to the present invention. FIGS. 3A to 3C and 4A to 4D represent this producing method as change of the cross-section corresponding to FIG. 1.

In this producing method, first, as shown in FIG. 3A, the metal supporting board 10 is prepared (preparation step). The metal supporting board 10 can be prepared by forming the surface metal layer 12 on the metal supporting layer 11 as a substrate. Examples of the method for forming the surface metal layer 12 include a sputtering method, a plating method, and a vacuum deposition method. The surface metal layer 12 is preferably formed by a plating method.

Next, as shown in FIG. 3B, the first metal thin film 21 is formed on the metal supporting board 10 (first metal thin film forming step). Examples of the method for forming the first metal thin film 21 include a sputtering method, a vacuum deposition method, and a plating method. The plating method includes electrolytic plating and electroless plating. The first metal thin film 21 is preferably formed by a sputtering method.

Next, as shown in FIG. 3C, the insulating layer 22 is formed on one surface in the thickness direction of the first metal thin film 21 (base insulating layer forming step). In this step, the insulating layer 22 is formed, for example, in the following manner. First, a solution (varnish) of a photosensitive resin is applied onto the first metal thin film 21 to form a coated film. Then, this coated film is dried by heating. Then, the dried coated film is subjected to an exposure process through a predetermined mask, and a subsequent development process, and thereafter, subjected to a baking process as required. For example, in the manner described above, the insulating layer 22 having the through hole 22a can be formed on the first metal thin film 21. In the through hole 22a, the portion 21a of the first metal thin film 21 is exposed.

Next, as shown in FIG. 4A, the second metal thin film 23 is formed (second metal thin film forming step). In this step, the second metal thin film 23 is continuously formed on one surface in the thickness direction of the insulating layer 22, on the inner wall surface 22b of the through hole 22a, and on the portion 21a of the first metal thin film 21 exposed in the through hole 22a (the second metal thin film 23 includes the second metal thin film 23A outside the through hole 22a and the second metal thin film 23B inside the through hole 22a). Examples of the method for forming the second metal thin film 23 include a sputtering method, a vacuum deposition method, and a plating method. The plating method includes electrolytic plating and electroless plating. The second metal thin film 23 is preferably formed by a sputtering method.

Next, as shown in FIG. 4B, the conductive layer 24 is formed on one surface in the thickness direction of the second metal thin film 23 (conductive layer forming step). Specific details are, for example, as follows.

First, a resist pattern is formed on the second metal thin film 23. The resist pattern has an opening having a shape corresponding to the pattern shape of the conductive layer 24. In the formation of the resist pattern, first, a photosensitive resist film is laminated on the second metal thin film 23 to form a resist film. Then, the resist film is subjected to an exposure process through a predetermined mask, and a subsequent development process, and thereafter, subjected to a baking process as required. In the formation of the conductive layer 24, then, for example, electrolytic plating is performed to grow the above-described metal on the second metal thin film 23 in the opening of the resist pattern. Then, the resist pattern is removed. For example, in the manner described above, the conductive layer 24 having a predetermined pattern can be formed on one surface in the thickness direction of the second metal thin film 23 (the conductive layer 24 includes the wire portion 24A on the second metal thin film 23A and the via portion 24B on the second metal thin film 23B).

In this producing method, next, as shown in FIG. 4C, a portion that is not covered with the conductive layer 24 in the second metal thin film 23 is removed by etching (etching step). In this manner, the wiring layer 31 (wire portion 24A, second metal thin film 23A) and the via 32 (via portion 24B, second metal thin film 23B, portion 21a) are formed. After this step, a nickel film may be formed on the surface of the wiring layer 31, for example, by electroless plating or electrolytic plating.

Next, as shown in FIG. 4D, the insulating layer 25 is formed on the insulating layer 22 so as to cover the wiring layer 31 and the via 32 (cover insulating layer forming step). In this step, the insulating layer 25 is formed, for example, in the following manner. First, a solution (varnish) of a photosensitive resin is applied onto the insulating layer 22, and onto the wiring layer 31 and the via 32 to form a coated film. Then, this coated film is dried. Then, the dried coated film is subjected to an exposure process through a predetermined mask, and a subsequent development process, and thereafter, subjected to a baking process as required. For example, in the manner described above, the insulating layer 25 as the cover insulating layer can be formed.

In this embodiment, next, the metal supporting board 10 is patterned by a process of etching the metal supporting board 10. This patterning includes, for example, a processing of forming an outer shape (a contour in plan view) of the metal supporting board 10, and a processing of forming, for example, an island portion separated from the surroundings in the metal supporting board 10. For example, after this step, a metal plating film may be formed on the exposed surface of the metal supporting board 10 by electrolytic plating or electroless plating. The exposed surface of the metal supporting board 10 specifically includes a surface that is not covered with the insulating layer 25 on one surface (surface metal layer 12) in the thickness direction of the metal supporting board 10, a side surface of the metal supporting board 10, and the other surface (lower surface in the figure) in the thickness direction of the metal supporting board 10.

In the manner described above, the wiring circuit board X1 can be produced.

In the wiring circuit board X1, as described above, the metal supporting board 10 includes the metal supporting layer 11, and the surface metal layer 12 disposed on one surface in the thickness direction of the metal supporting layer 11 and having higher conductivity than the metal supporting layer 11. The via 32 is connected to the surface metal layer 12 having higher conductivity than the metal supporting layer 11 in the metal supporting board 10. Therefore, the wiring circuit board X1 is suitable for establishing a low-resistance electrical connection between the wiring layer 31 disposed on one side in the thickness direction of the metal supporting board 10 and the metal supporting board 10.

In the wiring circuit board X1, as described above, the surface metal layer 12 having higher conductivity than the metal supporting layer 11 is disposed on one surface in the thickness direction of the metal supporting layer 11. Such a configuration, in which the metal supporting layer 11 and the surface metal layer 12 are directly in contact with each other without the other layer such as a Cr layer serving as a plating seed layer interposed therebetween, is suitable for efficiently patterning the metal supporting board 10 by a single process.

As described above, the wiring circuit board X1 is suitable for establishing a low-resistance electrical connection between the metal supporting board 10 and the wiring layer 31 formed on the insulating layer 22 on the metal supporting board 10, and is suitable for efficiently patterning the metal supporting board 10.

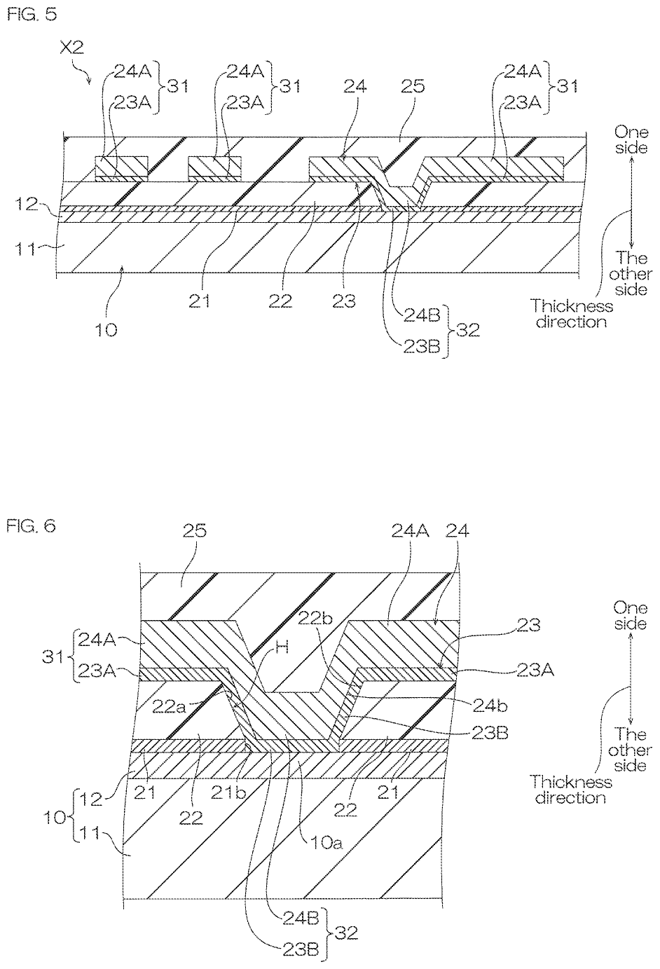

FIGS. 5 and 6 show a wiring circuit board X2 as another embodiment of the wiring circuit board of the present invention. The wiring circuit board X2 includes the metal supporting board 10, the first metal thin film 21, the insulating layer 22 as a base insulating layer, the second metal thin film 23, the conductive layer 24, and the insulating layer 25 as a cover insulating layer in order toward one side in the thickness direction. In the wiring circuit board X2, the first metal thin film 21 has an opening 21b, and the second metal thin film 23 is connected to the first metal thin film 21 in the opening 21b. Except this matter, the wiring circuit board X2 has the same configuration as the wiring circuit board X1.

In the wiring circuit board X2, the opening 21b of the first metal thin film 21 penetrates the first metal thin film 21 in the thickness direction. The opening 21b has, for example, a generally circular shape in plan view. The opening 21b is opened along the through hole 22a of the insulating layer 22. That is, the through hole 22a and the opening 21b are overlapped in plan view. The through hole 22a and the opening 21b form a through hole H.

In the wiring circuit board X2, the second metal thin film 23 is continuously disposed on one surface in the thickness direction of the insulating layer 22 and on a portion 10a (of the metal supporting board 10) facing the through hole H (the second metal thin film 23 includes the second metal thin film 23A outside the through hole H and the second metal thin film 23B inside the through hole H). The second metal thin film 23B is directly connected to the metal supporting board 10 at the through hole H.

In this embodiment, in the through hole H, the second metal thin film 23B and the via portion 24B on the second metal thin film 23B form the via 32. The via 32 is connected to the surface metal layer 12 having higher conductivity than the metal supporting layer 11 in the metal supporting board 10. The metal supporting board 10 and the wiring layer 31 are electrically connected through the via 32. The wiring layer 31 may be grounded through the via 32 and the metal supporting board 10.

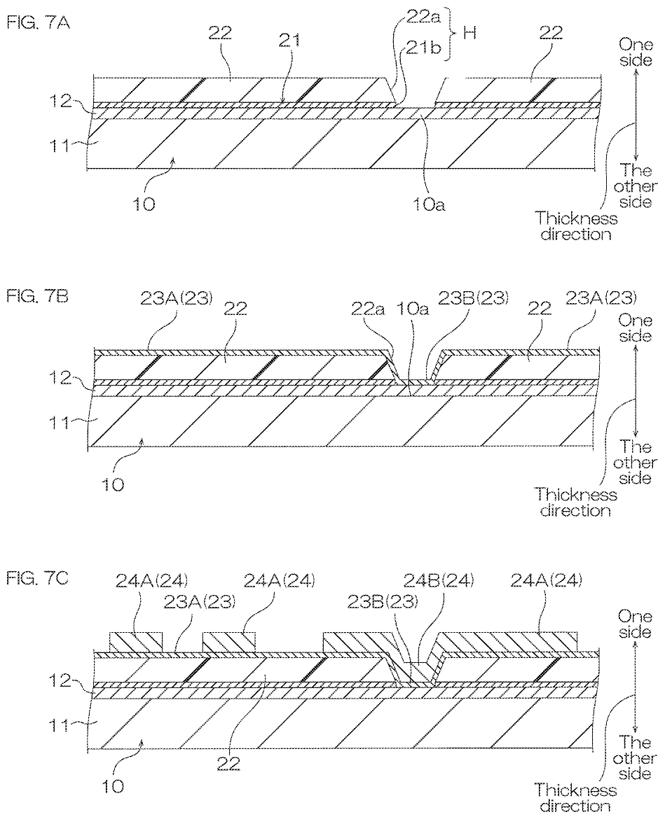

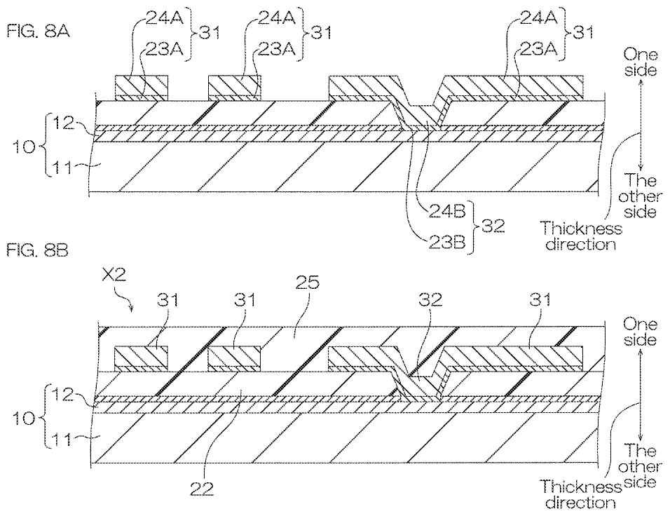

FIGS. 7A to 7C and 8A to 8B represent a part of the steps of a method for producing the wiring circuit board X2 as an embodiment of the method for producing the wiring circuit board according to the present invention. FIGS. 7A to 7C and 8A to 8B represent this producing method as change of the cross-section corresponding to FIG. 5.

In this producing method, first, in the same manner as described above with reference to FIGS. 3A to 3C, the preparation step, the first metal thin film forming step, and the base insulating layer forming step are performed.

Next, the portion 21a of the first metal thin film 21 exposed in the through hole 22a of the insulating layer 22 is removed. In this manner, as shown in FIG. 7A, a part (portion of the metal supporting board 10 is exposed in the through hole 22a (removing step). In this step, in the first metal thin film 21, the opening 21b is formed by removing the portion 21a (the opening 21b is opened along the through hole 22a, and the through hole 22a and the opening 21b form the through hole H).

For the removing method in this step, wet etching and dry etching are used, and wet etching is preferable. Examples of an etchant for the wet etching include a ceric ammonium nitrate solution, an aqueous solution of caustic soda, a potassium permanganate solution, and a sodium metasilicate solution, and preferably, a ceric ammonium nitrate solution is used. A temperature of the etchant in the wet etching is, for example, 20° C. or more, and preferably or more. The temperature of the etchant is, for example, 80° C. or less, preferably 65° C. or less. An etching time (immersion time) in the wet etching is, for example, 1 minute or more. The etching time is, for example, 15 minutes or less, preferably 10 minutes or less.

Next, as shown in FIG. 7B, the second metal thin film 23 is formed (second metal thin film forming step). In this step, the second metal thin film 23 is continuously formed on one surface in the thickness direction of the insulating layer 22 and on the portion 10a of the metal supporting board 10 exposed in the through hole H (the second metal thin film 23 includes the second metal thin film 23A outside the through hole 22a and the second metal thin film 23B inside the through hole 22a). Examples of the method for forming the second metal thin film 23 include a sputtering method, a vacuum deposition method, and a plating method. The plating method includes electrolytic plating and electroless plating. The second metal thin film 23 is preferably formed by a sputtering method.

Next, as shown in FIG. 7C, the conductive layer 24 is formed on one surface in the thickness direction of the second metal thin film 23 (conductive layer forming step). Specifically, this step is the same as the conductive layer forming step described above with reference to FIG. 4B.

Next, as shown in FIG. 8A, a portion that is not covered with the conductive layer 24 in the second metal thin film 23 is removed by etching (etching step). In this manner, the wiring layer 31 (wire portion 24A, second metal thin film 23A) and the via 32 (via portion 24B, second metal thin film 23B) are formed.

Next, as shown in FIG. 8B, the insulating layer 25 is formed on the insulating layer 22 so as to cover the wiring layer 31 and the via 32 (cover insulating layer forming step). Specifically, this step is the same as the cover insulating layer forming step described above with reference to FIG. 4D.

In this embodiment, next, the metal supporting board 10 is patterned by a process of etching the metal supporting board 10. This patterning includes, for example, a processing of forming an outer shape (a contour in plan view) of the metal supporting board 10, and a processing of forming, for example, an island portion separated from the surroundings in the metal supporting board 10.

In the manner described above, the wiring circuit board X2 can be produced.

In this producing method, the removing step (shown in FIG. 7A) is performed later than the base insulating layer forming step (shown in FIG. 3C). In the removing step, the portion 21a of the first metal thin film 21 is removed, and the metal supporting board 10 is then exposed in the through hole 22a. In this removing step, even if the surface of the portion 21a (shown in FIG. 3C) facing the through hole 22a in the first metal thin film 21 is oxidized, the portion 21a with an oxide film can be removed. In the subsequent second metal thin film forming step (shown in FIG. 7B), the second metal thin film 23B is formed on the portion 10a (of the metal supporting board 10) facing the through hole 22a. In the conductive layer forming step (shown in FIG. 7C), the via portion 24B is formed on the second metal thin film 23B. In this manner, the via 32 (second metal thin film 23B, via portion 24B) is formed in the through hole 22a.

Thus, according to this producing method, the via 32, which is connected to the metal supporting board 10 without through the first metal thin film 21, is formed. Therefore, this producing method is suitable for establishing a low-resistance electrical connection between the metal supporting board 10 and the wiring layer 31.

In the wiring circuit board X2, as in the wiring circuit board X1, the metal supporting board 10 includes the surface metal layer 12 disposed on one surface in the thickness direction of the metal supporting layer 11 and having higher conductivity than the metal supporting layer 11. The via 32 is connected to the surface metal layer 12 having higher conductivity than the metal supporting layer 11 in the metal supporting board 10. Accordingly, the wiring circuit board X2, as well as the wiring circuit board X1, is suitable for establishing a low-resistance electrical connection between the metal supporting board 10 and the wiring layer 31, and is suitable for efficiently patterning the metal supporting board 10.

The aforedescribed embodiments are illustrative of the present invention and should not be construed as being limited to the embodiments. Modification and variation of the present invention that will be obvious to those skilled in the art is to be covered by the following claims.

### INDUSTRIAL APPLICABILITY

The wiring circuit board of the present invention is applicable to a wiring circuit board including a metal supporting board as a supporting substrate.

### DESCRIPTION OF REFERENCE NUMERALS

X1, X2 wiring circuit boards
10 metal supporting board
11 metal supporting layer
12 surface metal layer
21 first metal thin film
21b opening
22 insulating layer
22a, H through hole
22b inner wall surface
23, 23A, 23B second metal thin film
24 conductive layer
24A wire portion
24B via portion
24b circumferential side surface
25 insulating layer
31 wiring layer
32 via

1. A wiring circuit board comprising
a metal supporting board; a first metal thin film; an insulating layer; a second metal thin film; and a conductive layer in order toward one side in a thickness direction,
the metal supporting board comprising a metal supporting layer, and a surface metal layer disposed on one surface in the thickness direction of the metal supporting layer and having a higher conductivity than the metal supporting layer,
the insulating layer having a through hole that penetrates the insulating layer in the thickness direction,
the conductive layer having a via portion that is disposed in the through hole and is electrically connected to the metal supporting board.

2. The wiring circuit board according to claim 1, wherein the metal supporting layer comprises at least one kind selected from the group consisting of stainless steel, copper alloy, aluminum, nickel, and titanium.

3. The wiring circuit board according to claim 1, wherein the surface metal layer comprises at least one kind selected from the group consisting of gold, silver, and copper.

4. The wiring circuit board according to claim 1, wherein the via portion is electrically connected to the metal supporting board through the first metal thin film and the second metal thin film.

5. The wiring circuit board according to claim 1, wherein the first metal thin film has an opening that is opened along the through hole, and the via portion is electrically connected to the metal supporting board through the second metal thin film.

6. A method for producing a wiring circuit board, comprising:
a first metal thin film forming step of forming a first metal thin film on one surface in a thickness direction of a metal supporting board comprising a metal supporting layer, and a surface metal layer disposed on one surface in the thickness direction of the metal supporting layer and having higher conductivity than the metal supporting layer;
an insulating layer forming step of forming an insulating layer on one surface in the thickness direction of the first metal thin film, the insulating layer having a through hole;
a second metal thin film forming step of forming a second metal thin film on one surface in the thickness direction of the insulating layer and on a portion of the first metal thin film, the portion being exposed in the through hole; and
a conductive layer forming step of forming a conductive layer on one surface in the thickness direction of the second metal thin film, the conductive layer including a via portion disposed in the through hole.

7. A method for producing a wiring circuit board, comprising:
a first metal thin film forming step of forming a first metal thin film on one surface in a thickness direction of a metal supporting board comprising a metal supporting layer, and a surface metal layer disposed on one surface in the thickness direction of the metal supporting layer and having higher conductivity than the metal supporting layer;
an insulating layer forming step of forming an insulating layer on one surface in the thickness direction of the first metal thin film, the insulating layer having a through hole;
a removing step of removing a portion of the first metal thin film, the portion being exposed in the through hole, to expose the metal supporting board in the through hole;
a second metal thin film forming step of forming a second metal thin film on one surface in the thickness direction of the insulating layer and on a portion of the metal supporting board, the portion being exposed in the through hole; and
a conductive layer forming step of forming a conductive layer on one surface in the thickness direction of the second metal thin film, the conductive layer including a via portion disposed in the through hole.
